(19) United States
(12) Patent Application Publication
(10) Pub. No.: US 2025/0201616 A1
(43) Pub. Date: Jun. 19, 2025

(54) SEMICONDUCTOR MANUFACTURING DEVICE AND SEMICONDUCTOR DEVICE MANUFACTURING METHOD

(71) Applicant: Kioxia Corporation, Tokyo (JP)

(72) Inventors: Yuusuke TAKANO, Yokkaichi Mie (JP); Tetsuya KUROSAWA, Yokkaichi Mie (JP); Hayato FURUICHI, Yokkaichi Mie (JP)

(73) Assignee: Kioxia Corporation, Tokyo (JP)

(21) Appl. No.: 18/828,710

(22) Filed: Sep. 9, 2024

(30) Foreign Application Priority Data
Dec. 19, 2023 (JP) 2023-214266

(51) Int. Cl. H01L 21/683

(52) U.S. Cl. CPC H01L 21/6835; H01L 21/6838; H01L 2221/68354; H01L 2221/68363

(57) ABSTRACT

A semiconductor manufacturing device is a semiconductor manufacturing device for connecting a semiconductor chip to a target object and includes a collet and a holder. The collet is formed of an elastic material and comes into contact with the semiconductor chip. The holder holds the collet. A recessed part into which the collet is inserted is formed at a front surface of the holder. A protrusion part is formed at a central part of a bottom surface of the recessed part, the amount of protrusion of the protrusion part being largest from the bottom surface of the recessed part relative to any other part of the bottom surface of the recessed part.

### CROSS-REFERENCE TO RELATED APPLICATION

This application is based upon and claims the benefit of priority from the prior Japanese Patent Applications No. 2023-214266, filed on Dec. 19, 2023, the entire contents of which are incorporated herein by reference.

### FIELD

Embodiments relate to a semiconductor manufacturing device and a semiconductor device manufacturing method.

### BACKGROUND

A semiconductor manufacturing device for connecting a semiconductor chip to a substrate has been known.

### BRIEF DESCRIPTION OF THE DRAWINGS

FIG. 1 is a front view illustrating a front structure of a semiconductor manufacturing device according to a first embodiment;

FIG. 2 is a perspective view illustrating a perspective structure of the semiconductor manufacturing device according to the first embodiment;

FIG. 3 is a perspective view illustrating a perspective structure of a holder according to the first embodiment;

FIG. 4 is a plan view illustrating a planar structure of the holder according to the first embodiment;

FIG. 5 is a cross-sectional view illustrating a sectional structure along a line V-V in FIG. 4;

FIG. 6 is a cross-sectional view illustrating a sectional structure along a line VI-VI in FIG. 2;

FIGS. 7A and 7B are a front view and a cross-sectional view, respectively, illustrating an operation example of the semiconductor manufacturing device according to the first embodiment;

FIGS. 8A and 8B are cross-sectional views each illustrating the operation example of the semiconductor manufacturing device according to the first embodiment;

FIGS. 9A and 9B are cross-sectional views each illustrating the operation example of the semiconductor manufacturing device according to the first embodiment;

FIGS. 10A to 10D are diagrams schematically illustrating change in pressure applied to a semiconductor chip according to the first embodiment;

FIG. 11 is a cross-sectional view illustrating a sectional structure of the semiconductor manufacturing device according to the first embodiment;

FIGS. 12A to 12D are diagrams schematically illustrating change in pressure applied to the semiconductor chip according to the first embodiment;

FIG. 13 is a plan view illustrating a planar structure of a holder according to a comparative example;

FIGS. 14A to 14D are diagrams schematically illustrating change in pressure applied to a semiconductor chip according to the comparative example;

FIG. 15 is a front view illustrating a front structure of each of a collet and a semiconductor chip C according to the comparative example;

FIG. 16 is a perspective view illustrating a perspective structure of a semiconductor manufacturing device according to a modification of the first embodiment;

FIG. 17 is a perspective view illustrating a perspective structure of a holder according to a second embodiment;

FIG. 18 is a plan view illustrating a planar structure of the holder according to the second embodiment;

FIG. 19 is a perspective view illustrating a perspective structure of a semiconductor manufacturing device according to the second embodiment;

FIG. 20 is a cross-sectional view illustrating a sectional structure along a line XX-XX in FIG. 19;

FIGS. 21A and 21B are cross-sectional views each illustrating an operation example of the semiconductor manufacturing device according to the second embodiment;

FIGS. 22A and 22B are front views illustrating a front structure of a collet according to another embodiment;

FIG. 23 is a bottom view illustrating a bottom surface structure of a collet according to the other embodiment; and

FIG. 24 is a front view illustrating a front structure of the collet according to the other embodiment.

### DETAILED DESCRIPTION

In general, according to the embodiment, a semiconductor manufacturing device is a semiconductor manufacturing device for connecting a semiconductor chip to a target object and includes a collet and a holder. The collet is formed of an elastic material and comes into contact with the semiconductor chip. The holder holds the collet. A recessed part into which the collet is inserted is formed at a front surface of the holder. A protrusion part is formed at a central part of a bottom surface of the recessed part, the amount of protrusion of the protrusion part being largest from the bottom surface of the recessed part relative to any other part of the bottom surface of the recessed part.

Embodiments will be described below with reference to the accompanying drawings. To facilitate understanding of the description, identical constituent components in the drawings are denoted by the same reference sign whenever possible, and duplicate description thereof is omitted.

### 1 First Embodiment

The following describes a semiconductor manufacturing device and a semiconductor device manufacturing method according to a first embodiment.

### 1.1 Overview of Semiconductor Manufacturing Device

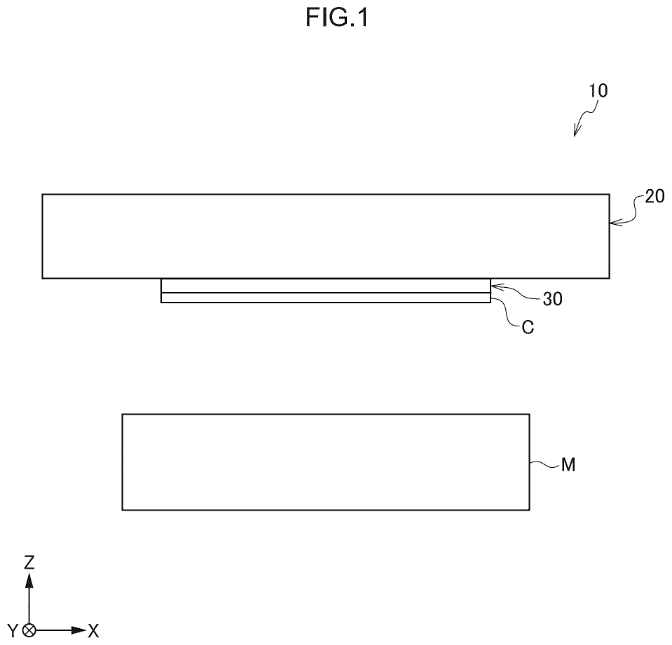

FIG. 1 is a front view illustrating a front structure of a semiconductor manufacturing device 10 according to the present embodiment. The semiconductor manufacturing device 10 according to the present embodiment is a device that connects a semiconductor chip C onto a substrate M. The semiconductor chip C is an unpackaged bare chip. The semiconductor manufacturing device 10 is what is called a flip chip bonding device that picks up the semiconductor chip C formed on a predetermined wafer, flips the semiconductor chip C, and then bonds the semiconductor chip C to the substrate M.

The semiconductor manufacturing device 10 may connect the semiconductor chip C to a predetermined wafer in place of the substrate M. The substrate M and the wafer are each an organic substrate with wiring formed on an upper surface, or a semiconductor element different from the semiconductor chip C. In the present embodiment, the substrate M and the wafer are examples of a target object to which the semiconductor chip C is connected.

### 1.2 Configuration of Semiconductor Manufacturing Device

The configuration of the semiconductor manufacturing device 10 will be specifically described below.

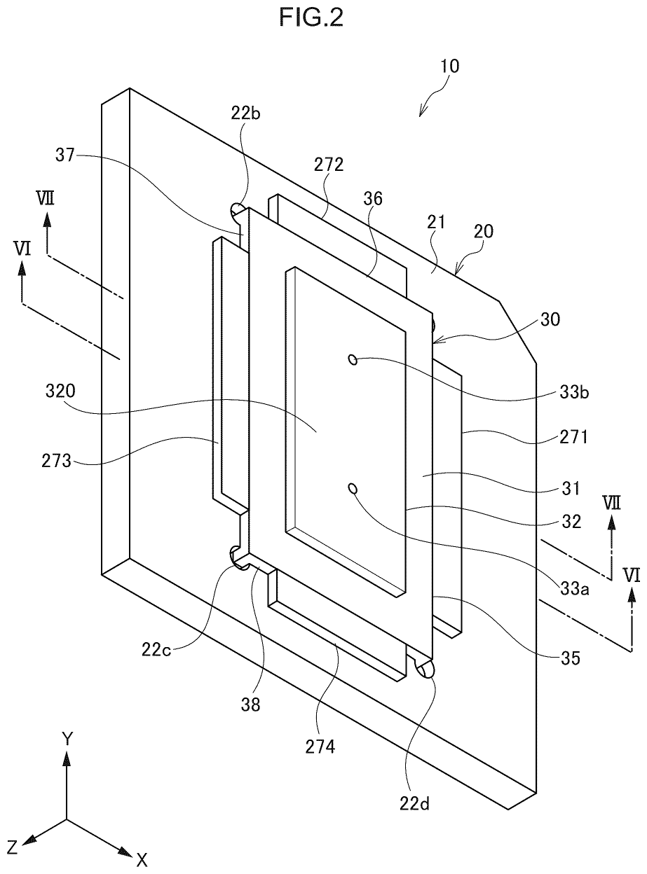

FIG. 2 is a perspective view illustrating a perspective structure of the semiconductor manufacturing device 10. As illustrated in FIG. 2, the semiconductor manufacturing device 10 includes a holder 20 and a collet 30.

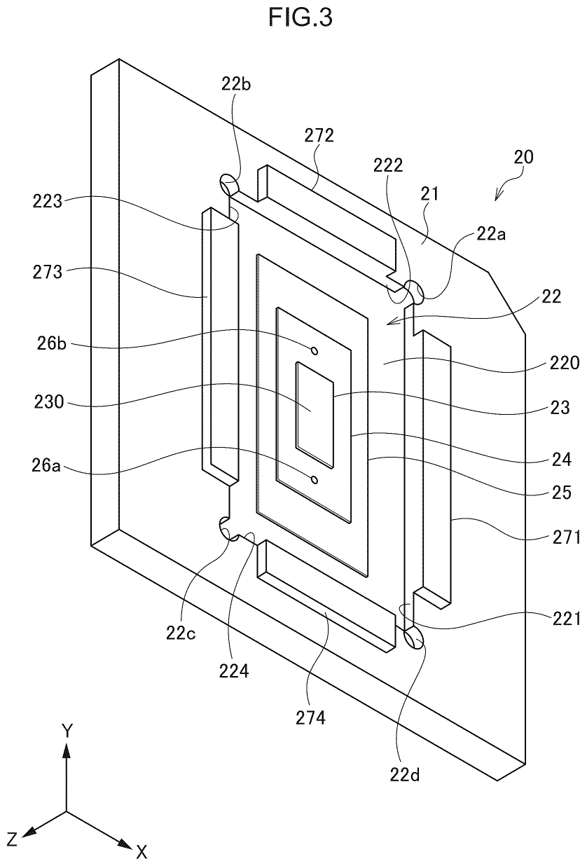

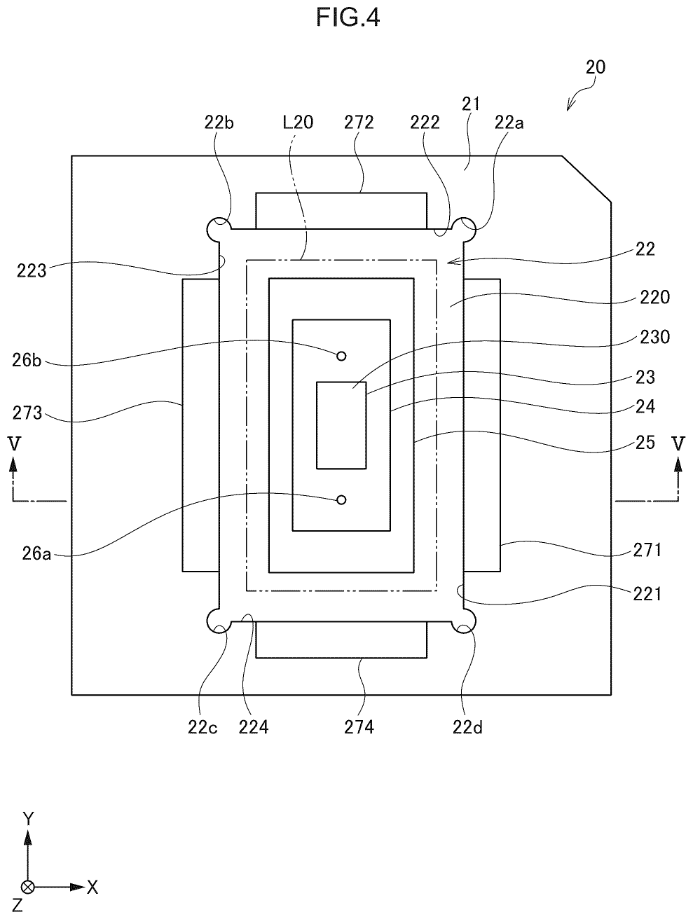

FIG. 3 is a perspective view illustrating a perspective structure of the holder 20. FIG. 4 is a plan view illustrating a planar structure of the holder 20. As illustrated in FIGS. 3 and 4, the holder 20 is formed in a thin rectangular parallelepiped shape. A recessed part 22 that has a rectangular parallelepiped shape and into which the collet 30 is inserted is formed at a central part of a front surface 21 of the holder 20. Corners 22a to 22d of the recessed part 22 are provided with relief processing. In the following description, the thickness direction of the holder 20 is referred to as a “Z direction”. In addition, the short side direction of the recessed part 22 is referred to as an “X direction”, and the longitudinal direction of the recessed part 22 is referred to as a “Y direction”.

A protrusion part 23 and step parts 24 and 25 are formed on a bottom surface 220 of the recessed part 22. The protrusion part 23 is formed substantially at the center of the bottom surface 220 of the recessed part 22. The protrusion part 23 is formed in a substantially rectangular parallelepiped shape having short sides in the X direction and long sides in the Y direction. The step part 24 is formed around the protrusion part 23 and has a shape larger than the protrusion part 23 in the X and Y directions and similar to the protrusion part 23. The step part 25 is formed around the step part 24 and has a shape larger than the step part 24 in the X and Y directions and similar to the step part 24. A dashed and double-dotted line L20 illustrated in FIG. 4 represents the outer edge of the semiconductor chip C. As illustrated in FIG. 4, the step part 25 has an outer edge slightly smaller than the outer edge of the semiconductor chip C.

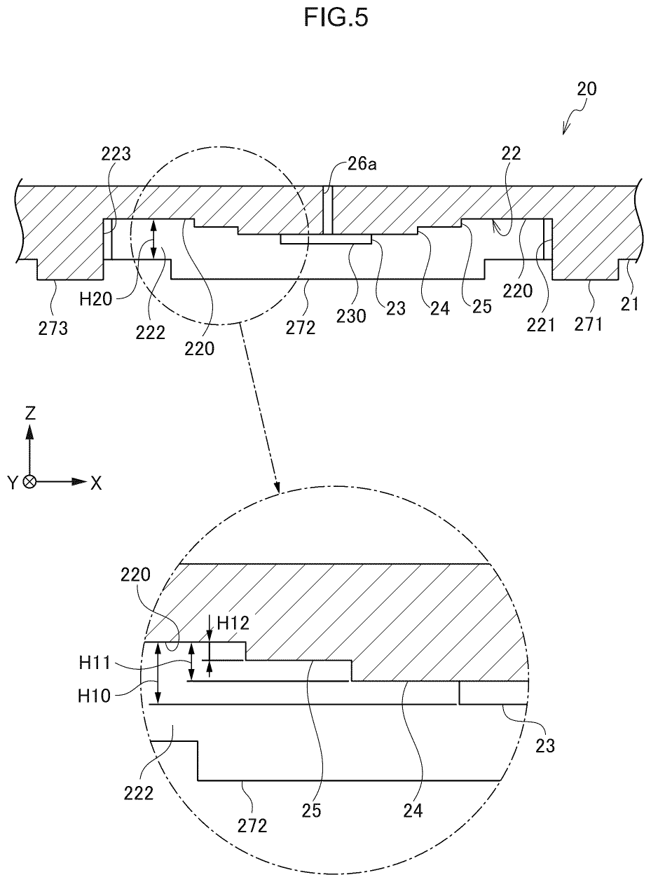

FIG. 5 is a cross-sectional view illustrating a sectional structure along a line V-V in FIG. 4. As illustrated in FIG. 5, “H10”, “H11”, and “H12” represent the protrusion amount of the protrusion part 23, the protrusion amount of the step part 24, and the protrusion amount of the step part 25, respectively, from the bottom surface 220 of the recessed part 22. The relation of “H10>H11>H12” holds among the protrusion amounts H10 to H12. In other words, the protrusion amounts of the protrusion part, the step part 24, and the step part 25 decrease in the stated order.

Reference signs 221 to 224 illustrated in FIGS. 3 and 4 denote respective side surfaces of the recessed part 22. In FIG. 5, “H20” represents the height of the side surface 222 from the bottom surface 220 of the recessed part 22. The other side surfaces 221, 223, and 224 have the same height H20. The relation of “H10<H20” holds between the protrusion amount H10 of the protrusion part 23 and the height H20 of the side surfaces 221 to 224 of the recessed part 22. In other words, the protrusion part 23 is formed lower than the height of the side surfaces 221 to 224 of the recessed part 22.

As illustrated in FIGS. 3 and 4, the step part 24 is provided with a plurality of ventilation holes 26a and 26b formed and opened at a top surface 240. The ventilation holes 26a and 26b are disposed alongside in the Y direction with the protrusion part 23 in between. As illustrated in FIG. 5, the ventilation hole 26a is formed to extend from the step part 24 to the inside of the holder 20. The ventilation hole 26b is formed in the same manner.

As illustrated in FIGS. 3 and 4, at the front surface 21 of the holder 20, side wall parts 271 to 274 are formed along the respective side surfaces 221 to 224 of the recessed part 22. The side wall part 271 is formed flush with the side surface 221 of the recessed part 22 and protruding from the front surface 21 of the holder 20. The other side wall parts 272 to 274 are formed in the same manner.

As illustrated in FIG. 2, the collet 30 is formed in a shape corresponding to the recessed part 22 of the holder 20, in other words, a thin rectangular parallelepiped shape having short sides in the X direction and long sides in the Y direction. The collet 30 is formed of, for example, a rubber elastic body mainly made of a natural rubber or a synthetic rubber having a hardness equal to or greater than Ha50 on the Shore A scale and equal to or less than Ha100 on the Shore A scale. Hardness on the Shore A scale is compliant with ISO868.

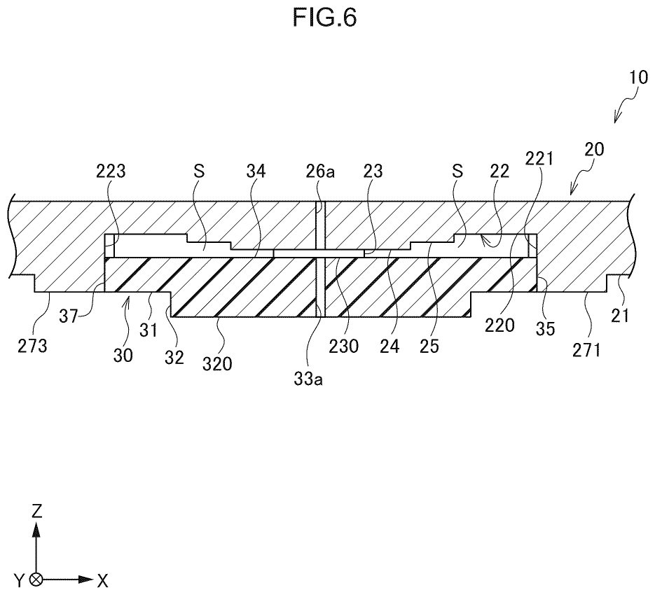

FIG. 6 is a cross-sectional view illustrating a sectional structure along a line VI-VI in FIG. 2, specifically, a sectional structure including the ventilation hole 26a of the holder 20. As illustrated in FIG. 6, a protrusion part 32 is formed on a front surface 31 of the collet 30. As illustrated in FIG. 2, the protrusion part 32 is formed in a substantially rectangular parallelepiped shape having short sides in the X direction and long sides in the Y direction. The protrusion part 32 has a substantially same size as the semiconductor chip C in the X and Y directions. The protrusion part 32 is provided with a plurality of through-holes 33a and 33b formed and opened at a top surface 320. As illustrated in FIG. 6, the through-hole 33a is formed to penetrate through the inside of the collet 30 from the top surface 320 of the protrusion part 32 to a back surface 34 of the collet 30 opposite the top surface 320. The through-hole 33a is disposed at a position that faces the ventilation hole 26a of the holder 20 in the Z direction. Similarly, the through-hole 33b is formed through the inside of the collet 30 and disposed at a position that faces the ventilation hole 26b of the holder 20 in the Z direction. Reference signs 35 to 38 illustrated in FIG. 2 denote respective side surfaces of the collet 30.

As illustrated in FIG. 6, the collet 30 is inserted into the recessed part 22 of the holder 20. The back surface 34 of the collet 30 contacts a top surface 230 of the protrusion part 23 of the holder 20. The side surface 35 of the collet 30 contacts the side surface 221 of the recessed part 22 and the inner surface of the side wall part 271. Similarly, the side surface 37 of the collet 30 contacts the side surface 223 of the recessed part 22 and the inner surface of the side wall part 273. The side surface 36 of the collet 30 contacts the side surface 222 of the recessed part 22 and the inner surface of the side wall part 272, and the side surface 38 of the collet 30 contacts the side surface 224 of the recessed part 22 and the side wall part 274. The collet 30 is held to the holder 20 by frictional force acting at these contact parts. A space S is surrounded and formed by the back surface 34 of the collet 30 and the recessed part 22 of the holder 20 illustrated in FIG. 6. In the following description, the space S is referred to as the “internal space S”.

### 1.3 Operation Example of Semiconductor Manufacturing Device

The following describes an operation example of the semiconductor manufacturing device 10 according to the present embodiment.

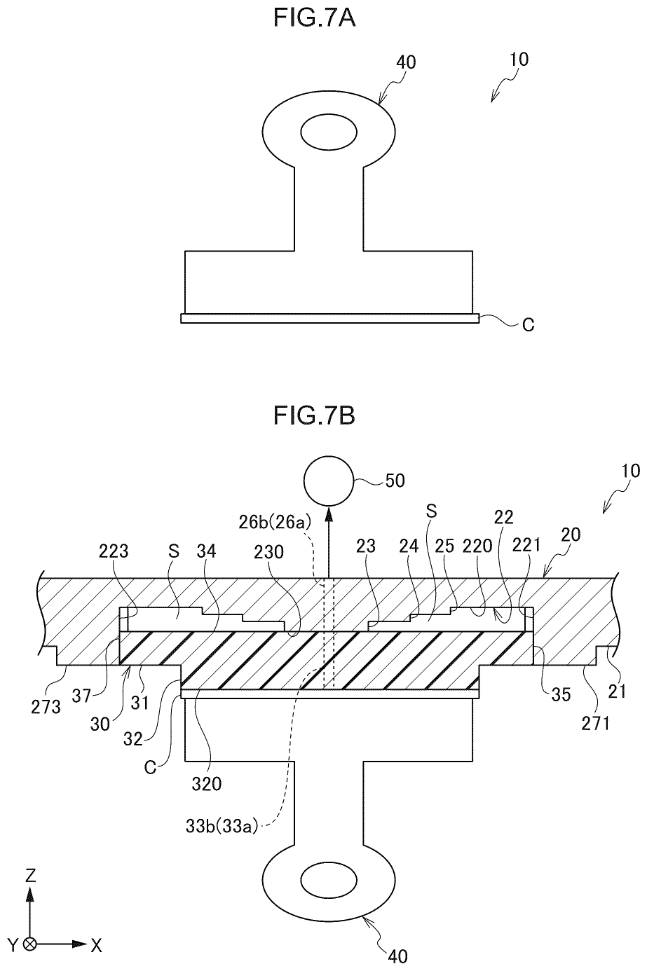

The semiconductor manufacturing device 10 further includes a flipper 40 as illustrated in FIG. 7A. As illustrated in FIG. 7A, the flipper 40 picks up the semiconductor chip C formed on a predetermined wafer. Thereafter, as illustrated in FIG. 7B, the flipper 40 is vertically flipped and then the semiconductor chip C is made contact with the top surface 320 of the protrusion part 32 of the collet 30. FIG. 7B is a cross-sectional view illustrating a sectional structure along a line VII-VII illustrated in FIG. 2, specifically, a sectional structure including the protrusion part 23.

Subsequently, air in the internal space S is sucked through the ventilation holes 26a and 26b of the holder 20 by a vacuum pump 50 to create a negative pressure inside the internal space S. Accordingly, the collet 30 is held in contact with the top surface 230 of the protrusion part 23 of the holder 20. Along with the suction of air in the internal space S by the vacuum pump 50, air in the through-holes 33a and 33b of the collet 30 is sucked, and accordingly, a negative pressure is created inside the through-holes 33a and 33b of the collet 30 as well. As a result, force occurs which causes the semiconductor chip C in contact with the front surface 31 of the collet 30 to be adhered to the collet 30 by suction. With the suction adhesive force, the semiconductor chip C is held in a state of being adhered to the collet 30 by suction. The collet 30 has such a hardness that the collet 30 is unlikely to deform when the internal space S has a negative pressure.

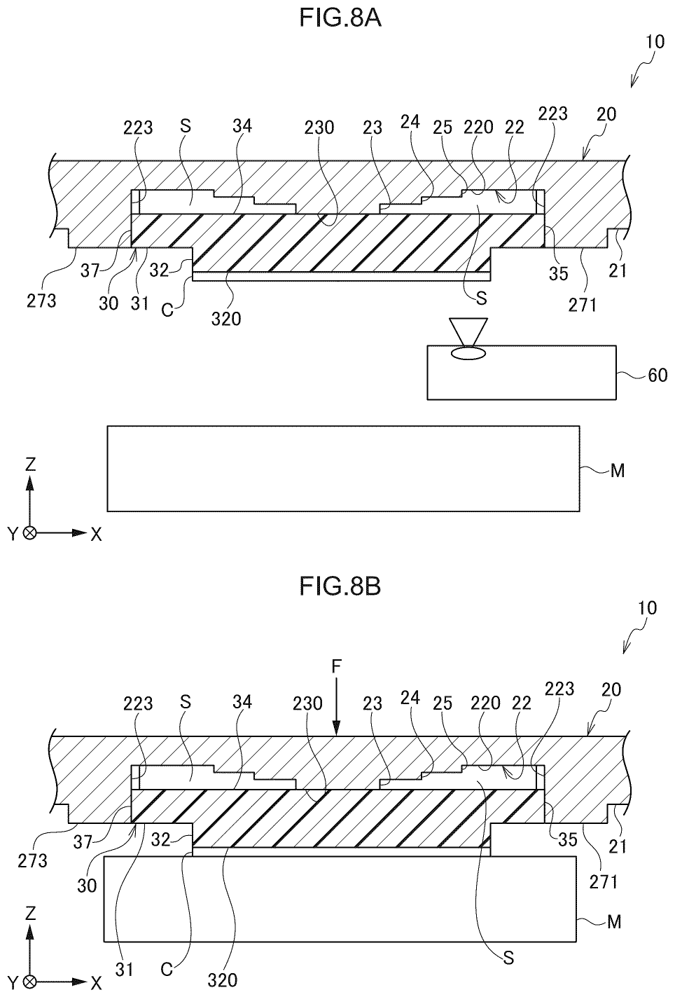

Thereafter, the flipper 40 is separated from the semiconductor chip C and then the semiconductor chip C is moved to above the substrate M as illustrated in FIG. 8A while the state of being held to the collet 30 is maintained. Then, the position of a predetermined mark provided at the semiconductor chip C is recognized by a camera 60 to perform positioning of the semiconductor chip C so that a position where the semiconductor chip C is to be connected onto the substrate M and the position of the semiconductor chip C being held to the collet 30 coincide with each other in the up-down direction.

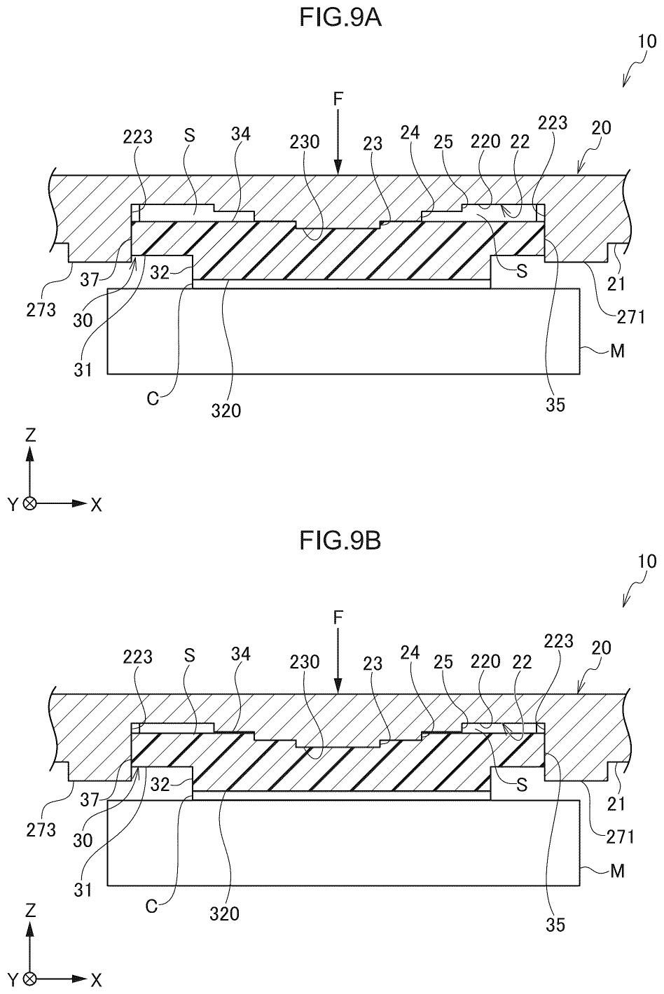

After the positioning of the semiconductor chip C is completed, the holder 20 is displaced toward the substrate M while the state in which the semiconductor chip C is held to the collet 30 is maintained, and accordingly, the semiconductor chip C is made contact with the substrate M as illustrated in FIG. 8B and then the holder 20 is pressed toward the substrate M by predetermined external force F. Accordingly, the collet 30 gradually elastically deforms as illustrated in FIGS. 9A and 9B and the back surface 34 of the collet 30 contacts the protrusion part 23, the step part 24, the step part 25, and the bottom surface 220 of the recessed part 22 in the stated order. Thus, pressure applied from the holder 20 to the collet 30 gradually changes.

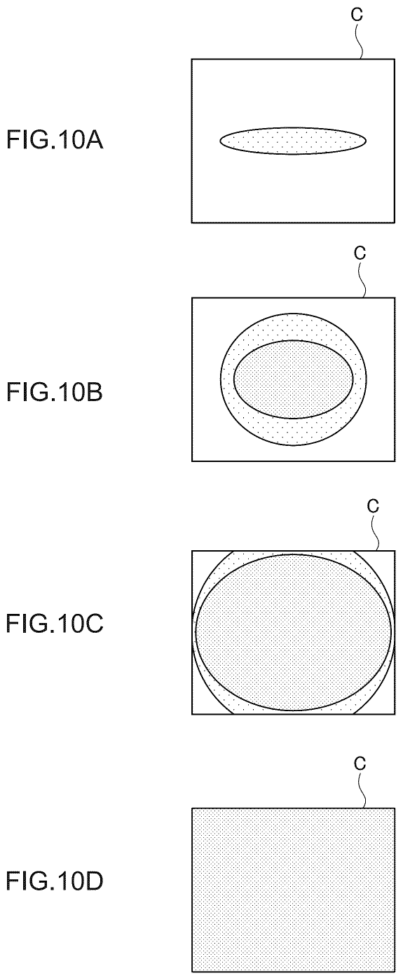

Specifically, in a state in which only the protrusion part 23 of the holder 20 is in contact with the back surface 34 of the collet 30 as illustrated in FIG. 8B, pressure is applied from the holder 20 to the collet 30 only through the protrusion part 23. Thus, in the state illustrated in FIG. 8B, pressure is likely to be applied near a central part of the semiconductor chip C as illustrated in FIG. 10A. In FIGS. 10A to 10D, parts of the semiconductor chip C where pressure is applied from the collet 30 are hatched with dots. In the hatching with dots, higher density of dots represents larger applied pressure.

Subsequently, when the step part 24 of the holder 20 further contacts the back surface 34 of the collet 30 as illustrated in FIG. 9A, pressure is applied from the holder 20 to the collet 30 through the protrusion part 23 and the step part 24. Thus, in the state illustrated in FIG. 9A, pressure is further likely to be applied to not only near the central part of the semiconductor chip C but also its outer peripheral part as illustrated in FIG. 10B.

Subsequently, when the step part 25 of the holder 20 further contacts the back surface 34 of the collet 30 as illustrated in FIG. 9B, pressure is applied from the holder 20 to the collet 30 through the protrusion part 23 and the step parts 24 and 25. Thus, in the state illustrated in FIG. 9B, pressure is further likely to be applied to a substantially entire region of the semiconductor chip C as illustrated in FIG. 10C. Thereafter, appropriate pressure is applied to the entire region of the semiconductor chip C as illustrated in FIG. 10D.

### 1.4 Effects of Semiconductor Manufacturing Device According to First Embodiment

As described above, the semiconductor manufacturing device 10 according to the present embodiment includes the holder 20 and the collet 30. The collet 30 is formed of an elastic material and comes into contact with the semiconductor chip C. The holder 20 holds the collet 30. The recessed part 22 into which the collet 30 is inserted is formed at the front surface 21 of the holder 20. The protrusion part 23 is formed at the central part of the bottom surface 220 of the recessed part 22, the amount of protrusion of the protrusion part 23 being largest from the bottom surface 220 of the recessed part 22 relative to any other part of the bottom surface 220 of the recessed part 22. The step parts 24 and 25 having smaller amounts of protrusion from the bottom surface 220 of the recessed part 22 than the amount of protrusion of the protrusion part 23 are formed around the protrusion part 23. The plurality of step parts 24 and 25 are formed such that the amount of protrusion decreases stepwise outward away from the protrusion part 23.

With this configuration, the protrusion part 23, the step part 24, and the step part 25 of the holder 20 contact the collet 30 in the stated order when the holder 20 is pressed toward the substrate M. Accordingly, pressure can be gradually applied toward the outside from the central part of the semiconductor chip C as illustrated in FIGS. 10A to 10D. Accordingly, a void is unlikely to be formed between the substrate M and the semiconductor chip C, and thus the semiconductor chip can be more appropriately connected onto the substrate M.

In the holder 20, the ventilation holes 26a and 26b opened at the bottom surface 220 of the recessed part 22 are formed only at the step part 24. In the collet 30, there are formed the through-holes 33a and 33b penetrating from the front surface 31 that contacts the semiconductor chip C to the back surface 34 that faces the bottom surface 220 of the recessed part 22 of the holder 20. The semiconductor chip C can be held in contact with the collet 30 by applying a vacuum through the ventilation holes 26a and 26b of the holder 20 and the through-holes 33a and 33b of the collet 30.

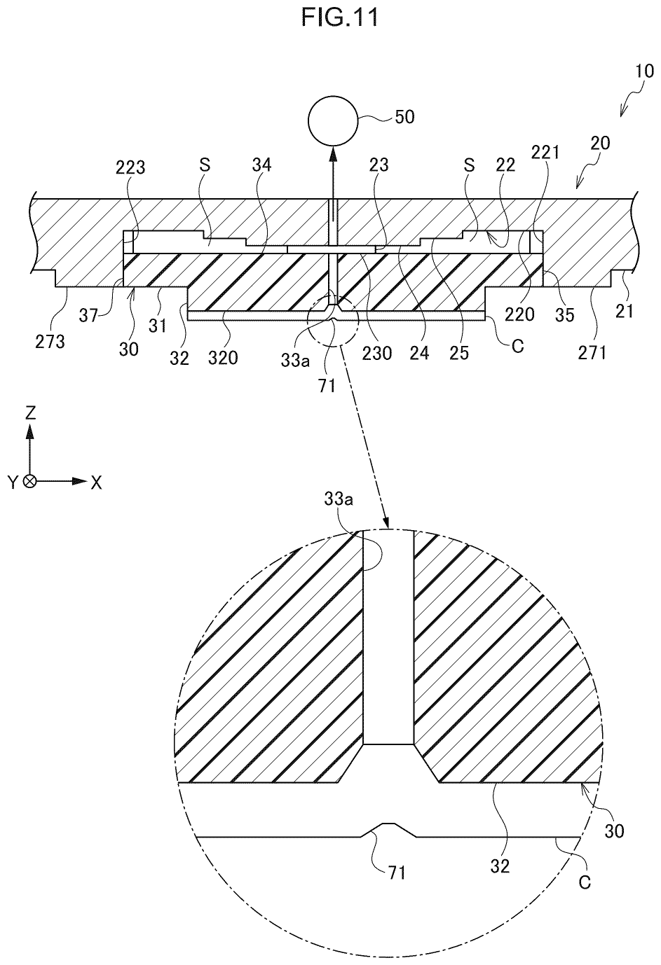

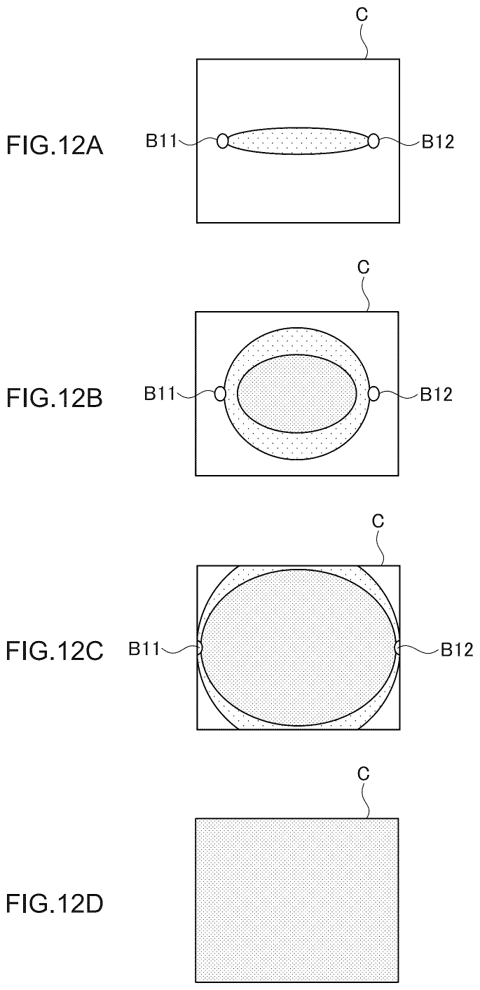

In the semiconductor manufacturing device 10 according to the present embodiment, when the semiconductor chip C is adhered to the collet 30 by suction, a part 71 of the semiconductor chip C, which corresponds to the through-hole 33a of the collet 30 potentially slightly deforms in a concave shape by being sucked into the through-holes 33a and 33b of the collet 30 as illustrated in FIG. 11. The same slight deformation of the semiconductor chip C potentially occurs also at a part facing the through-hole 33b of the collet 30. In a case where the semiconductor chip C slightly deforms in this manner, voids B11 and B12 are potentially formed between the semiconductor chip C and the substrate M, for example, as illustrated in FIG. 12A when the semiconductor chip C contacts the substrate M. However, with the semiconductor manufacturing device 10 according to the present embodiment, pressure is gradually applied from the central part of the semiconductor chip C toward the outside, and thus even when the voids B11 and B12 are formed between the semiconductor chip C and the substrate M, the voids B11 and B12 flow to the outside by pressing and are removed as illustrated in FIGS. 12B to 12D. Accordingly, the voids B11 and B12 are unlikely to remain between the semiconductor chip C and the substrate M.

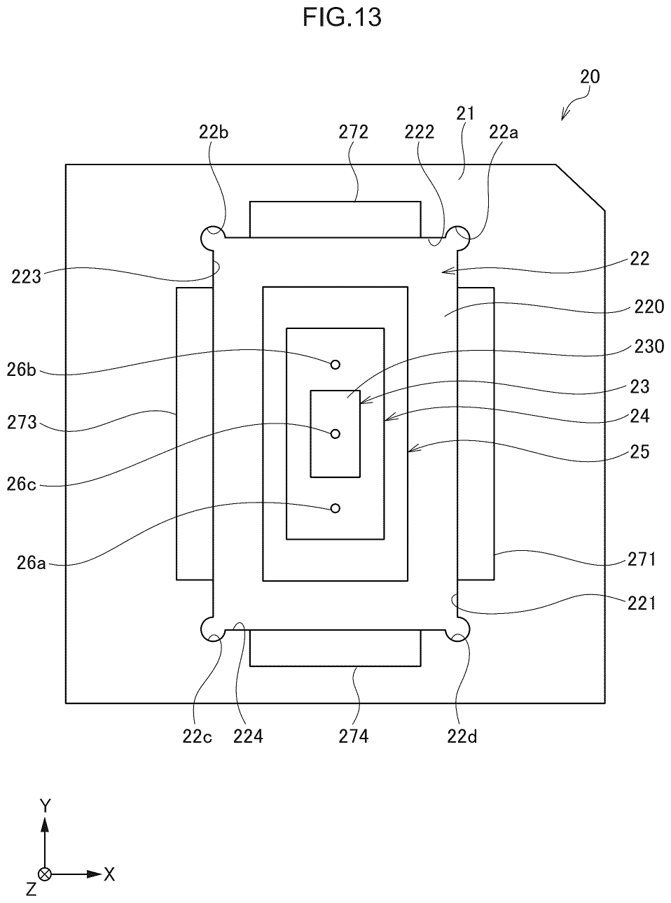

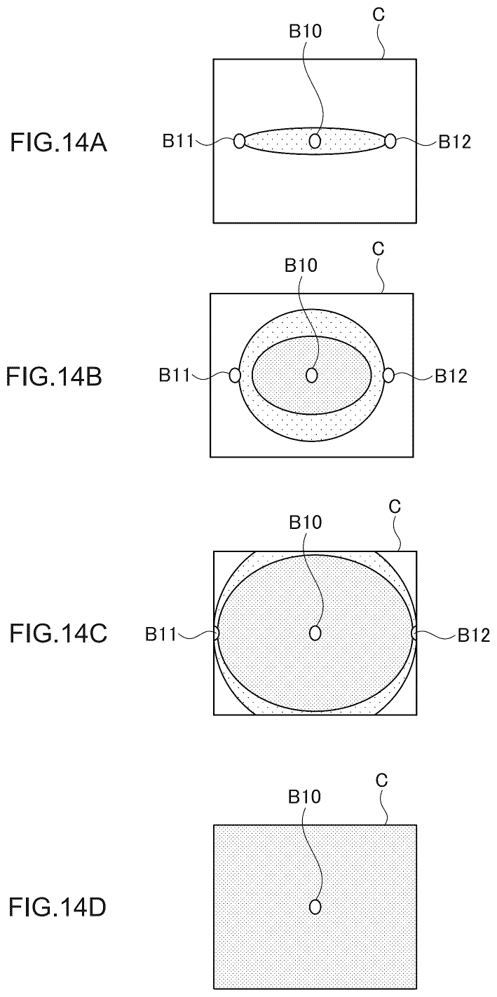

In a case where a ventilation hole 26c is formed in the protrusion part 23 and a through-hole corresponding to the ventilation hole 26c is formed in the collet 30 as illustrated in FIG. 13, the central part of the semiconductor chip C potentially slightly deforms in a concave shape when the semiconductor chip C is adhered to the collet 30 by suction. In this case, a void B10 is potentially further formed between a central part 70 of the semiconductor chip C and the substrate M as illustrated in FIG. 14A. In a case where such a void B10 is formed, the void B10 potentially does not flow to the outside by pressing but remains even when pressure is gradually applied from the central part 70 of the semiconductor chip C toward the outside as illustrated in FIGS. 14B to 14D.

However, in the semiconductor manufacturing device 10 according to the present embodiment, no ventilation hole is formed in the protrusion part 23 as illustrated in FIGS. 3 and 4, and thus the void B10 as illustrated in FIG. 14C is unlikely to be formed. Accordingly, such a situation that the void B10 remains can be avoided.

The collet 30 has a hardness equal to or greater than Ha50 on the Shore A scale and equal to or less than Ha100 on the Shore A scale.

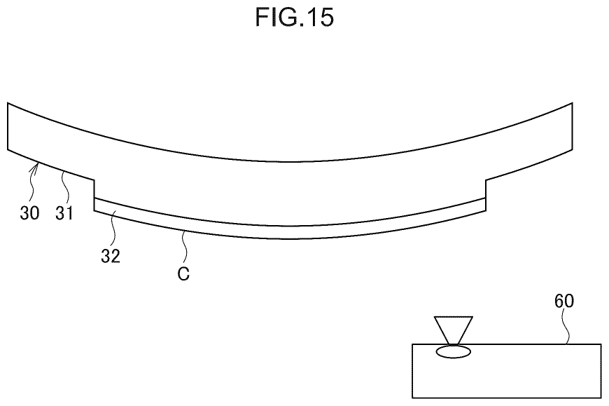

In a case where the hardness of the collet 30 is low, the collet 30 potentially curves as illustrated in, for example, FIG. 15 when a negative pressure is created inside the internal space S by the vacuum pump 50. In a case where the collet 30 curves in this manner, the semiconductor chip C potentially curves along the shape of the collet 30 when the semiconductor chip C is adhered to the collet 30 by suction. In a case where the semiconductor chip C curves in this manner, the position of the semiconductor chip C potentially cannot be accurately detected when the position of the semiconductor chip C is detected by the camera 60.

However, the collet 30 according to the present embodiment has the hardness as described above and thus holds the original shape as illustrated in FIG. 8A even when a negative pressure is created inside the internal space S. Accordingly, the semiconductor chip C is unlikely to curve when the semiconductor chip C is adhered to the collet 30 by suction, and thus the position of the semiconductor chip C can be more accurately detected by the camera 60. As a result, the semiconductor chip C can be more accurately connected to the substrate M.

The collet 30 has the hardness as described above and thus elastically deforms as illustrated in FIGS. 9A and 9B when the holder 20 is pressed toward the substrate M by predetermined external force F. Accordingly, pressure can be gradually applied from the central part of the semiconductor chip C toward the outside as illustrated in FIGS. 10A to 10C.

The side wall parts 271 to 274 are formed on the holder 20 such that side wall parts are flush with the side surfaces 221 to 224 of the recessed part 22 and protrude from the front surface 21 of the holder 20.

With this configuration, the side surfaces 35 to 38 of the collet 30 contact the respective side wall parts 271 to 274 of the holder 20, and thus the collet 30 can be easily held by the holder 20.

### 1.5 Modification of Semiconductor Manufacturing Device According to First Embodiment

The following describes a modification of the semiconductor manufacturing device according to the first embodiment.

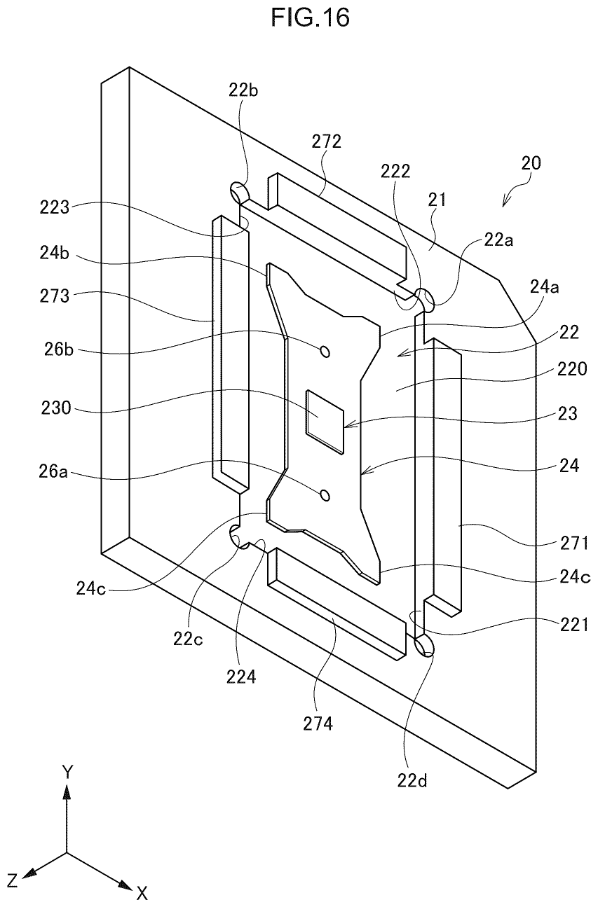

FIG. 16 is a perspective view illustrating a perspective structure of the holder 20 according to the present modification. As illustrated in FIG. 16, the protrusion part 23 and the step part 24 are formed in the recessed part 22 of the holder 20 according to the present modification. Corners 24a to 24d of the step part 24 are deformed to extend toward the respective corners 22a to 22d of the recessed part 22 of the holder 20.

With this configuration, pressure is likely to be applied near corners 30a to 30d of the collet 30 from the corners 24a to 24d of the step part 24 when the holder 20 is pressed toward the substrate M by predetermined external force F and the step part 24 contacts the back surface 34 of the collet 30. Accordingly, pressure is likely to be more uniformly applied to the collet 30 from the holder 20, and thus the semiconductor chip C can be more appropriately connected to the substrate M.

### 2 Second Embodiment

The following describes the semiconductor manufacturing device 10 according to a second embodiment. The description is mainly made on difference from the semiconductor manufacturing device 10 according to the first embodiment.

### 2.1 Configuration of Semiconductor Manufacturing Device

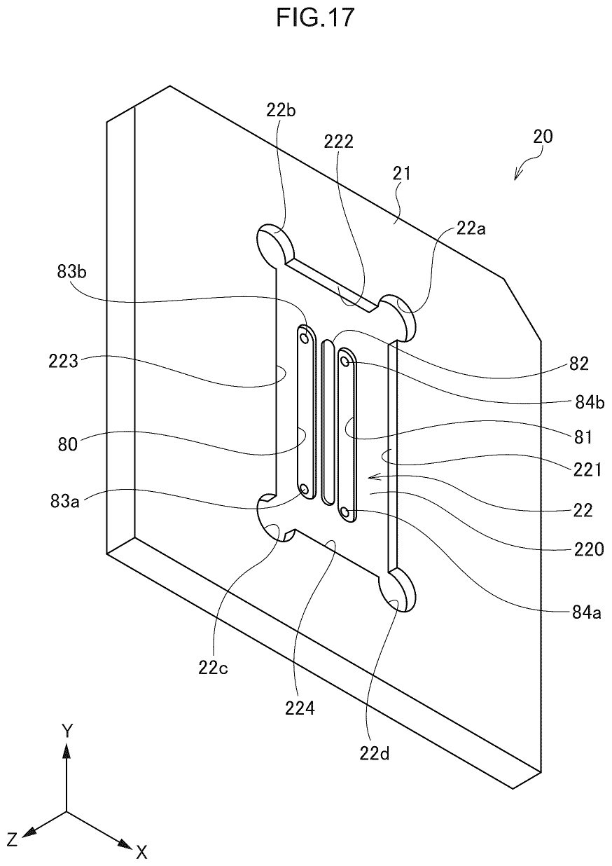

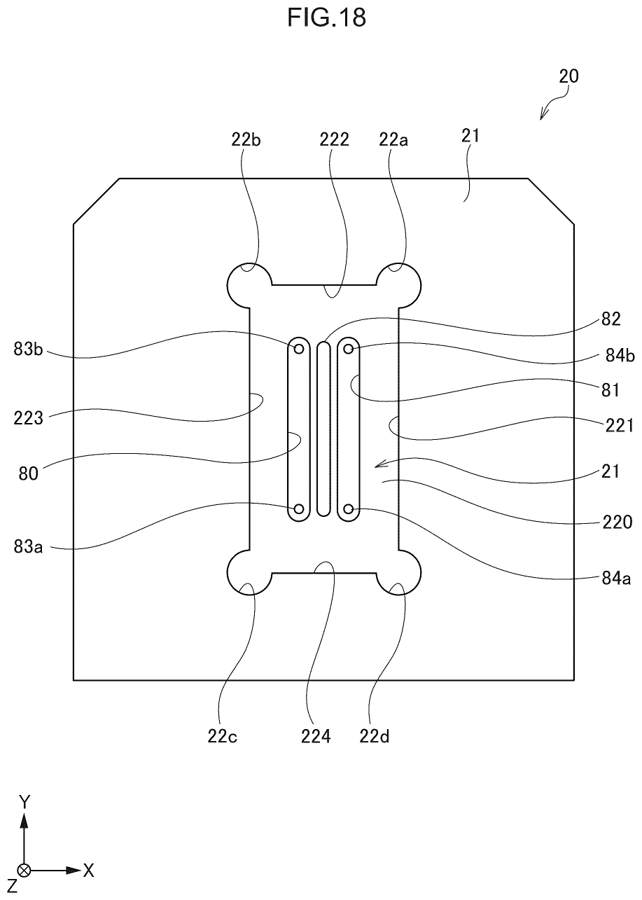

FIG. 17 is a perspective view illustrating a perspective structure of the holder 20 according to the present embodiment. FIG. 18 is a plan view illustrating a planar structure of the holder 20 according to the present embodiment. As illustrated in FIGS. 17 and 18, two groove parts 80 and 81 and a protrusion part 82 are formed in the bottom surface 220 of the recessed part 22 of the holder 20. The two groove parts 80 and 81 are formed in an elongated hole shape extending in the Y direction and disposed alongside in the X direction. Ventilation holes 83a and 83b are formed at respective end parts of the groove part 80. Similarly, ventilation holes 84a and 84b are formed at respective end parts of the groove part 81. The protrusion part 82 is formed between the two groove parts 80 and 81. The protrusion part 82 is formed to protrude from the bottom surface 220 of the recessed part 22 and extend in an elongated shape along the groove parts 80 and 81. In the present embodiment, the groove parts 80 and 81 are examples of two predetermined groove parts adjacent to each other.

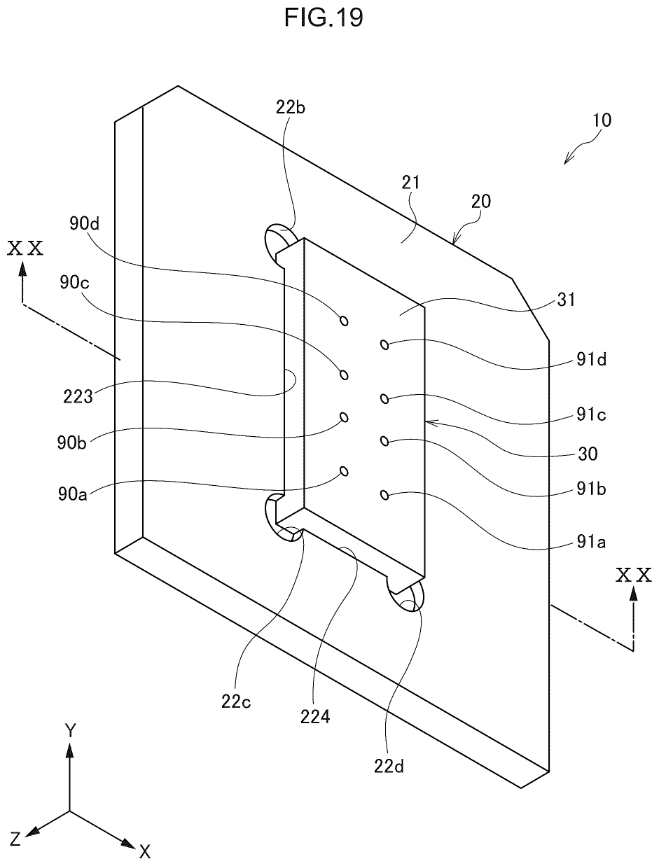

FIG. 19 is a perspective view illustrating a perspective structure of the semiconductor manufacturing device 10 according to the present embodiment. As illustrated in FIG. 19, the collet 30 is inserted into the recessed part 22 of the holder 20. The collet 30 is formed in a rectangular parallelepiped shape. A plurality of through-holes 90a to 90d and 91a to 91d are formed in the collet 30. The through-holes 90a to 90d are disposed alongside at a predetermined interval in the Y direction. Similarly, the through-holes 91a to 91d are disposed alongside at a predetermined interval in the Y direction.

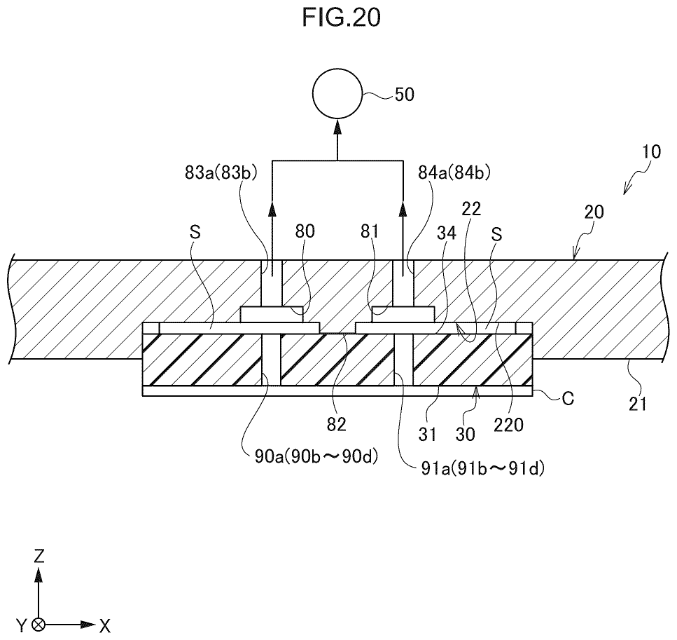

FIG. 20 is a cross-sectional view illustrating a sectional structure along a line XVII-XVII in FIG. 19. As illustrated in FIG. 20, the plurality of through-holes 90a to 90d and 91a to 91d are formed to penetrate from the front surface 31 of the collet 30 to the back surface 34. The through-holes 90a to 90d are disposed at positions that face the groove part 80 of the holder 20. The through-holes 91a to 91d are disposed at positions that face the groove part 81 of the holder 20.

### 2.2 Operation Example of Semiconductor Manufacturing Device

The following describes an operation example of the semiconductor manufacturing device 10 according to the present embodiment.

In the semiconductor manufacturing device 10 according to the present embodiment, as illustrated in FIG. 20, air in the internal space S is sucked through the ventilation holes 83a, 83b, 84a, and 84b of the holder 20 by the vacuum pump 50 to create a negative pressure inside the internal space S. Accordingly, the collet 30 is held in a state of being adhered to the holder 20 by suction. Along with the suction of air in the internal space S by the vacuum pump 50, a negative pressure is also created inside the through-holes 90a to 90d and 91a to 91d of the collet 30. Accordingly, the semiconductor chip C is held in a state of being adhered to the collet 30 by suction.

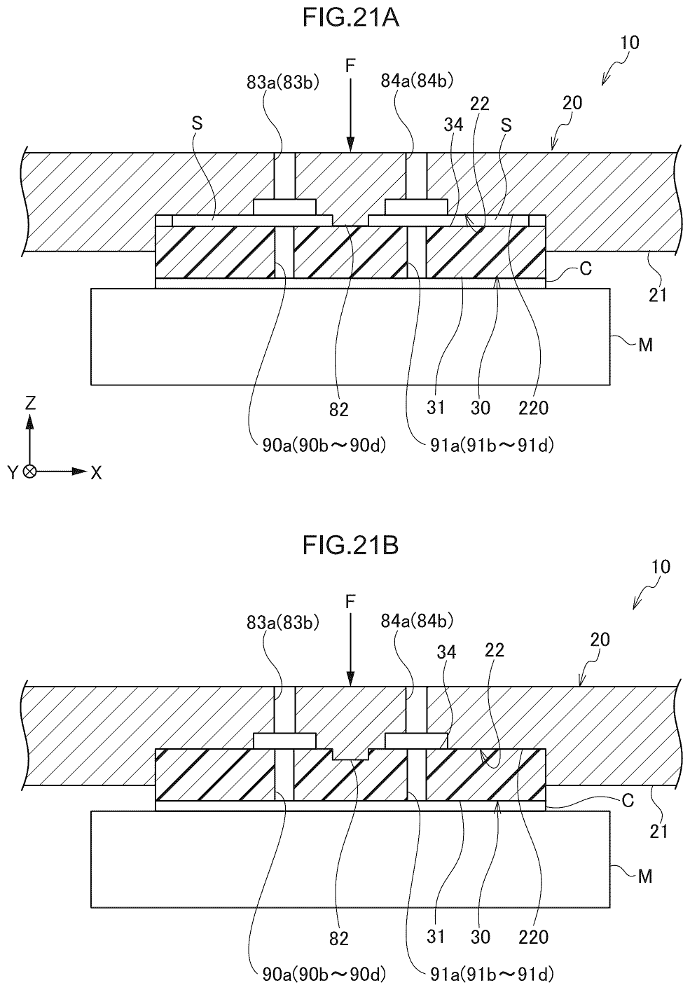

Subsequently, the semiconductor chip C is made contact with the substrate M while the state of being held to the collet 30 is maintained, and then the holder 20 is pressed toward the substrate M by predetermined external force F. Accordingly, the collet 30 gradually deforms as illustrated in FIGS. 21A and 21B, and as a result, the back surface 34 of the collet 30 contacts the protrusion part 82 and the bottom surface 220 of the recessed part 22 in the stated order. In this manner, pressure applied to the collet 30 from the holder 20 can be gradually changed.

Specifically, in a state in which only the protrusion part 82 of the holder 20 is in contact with the back surface 34 of the collet 30 as illustrated in FIG. 21A, pressure is applied from the holder 20 to the collet 30 only through the protrusion part 82. Thus, in the state illustrated in FIG. 21B, pressure is likely to be applied near the central part of the semiconductor chip C.

Subsequently, when the bottom surface 220 of the recessed part 22 further contacts the back surface 34 of the collet 30 as illustrated in FIG. 21B, pressure is applied from the holder 20 to the collet 30 through the protrusion part 82 and the bottom surface 220 of the recessed part 22. Thus, in the state illustrated in FIG. 21B, pressure is further likely to be applied not only near the central part of the semiconductor chip C but also its outer peripheral part.

### 2.3 Effects of Semiconductor Manufacturing Device According to Second Embodiment

As described above, in the collet 30 according to the present embodiment, there are formed the through-holes 90a to 90d and 91a to 91d penetrating from the front surface 31 that contacts the semiconductor chip C to the back surface 34 that faces the plurality of groove parts 80 and 81. The semiconductor chip C can be held in contact with the collet 30 by applying a vacuum through the ventilation holes 83a, 83b, 84a, and 84b of the holder 20 and the through-holes 90a to 90d and 91a to 91d of the collet 30. The protrusion part 82 is formed to extend in an elongated shape along the two adjacent groove parts 80 and 81.

With this configuration, as in the first embodiment, pressure can be gradually applied from the central part of the semiconductor chip C toward the outside. Accordingly, voids are unlikely to be formed between the substrate M and the semiconductor chip C, and thus the semiconductor chip can be more appropriately connected onto the substrate M.

### 3 Other Embodiments

The present disclosure is not limited to the above-described specific examples.

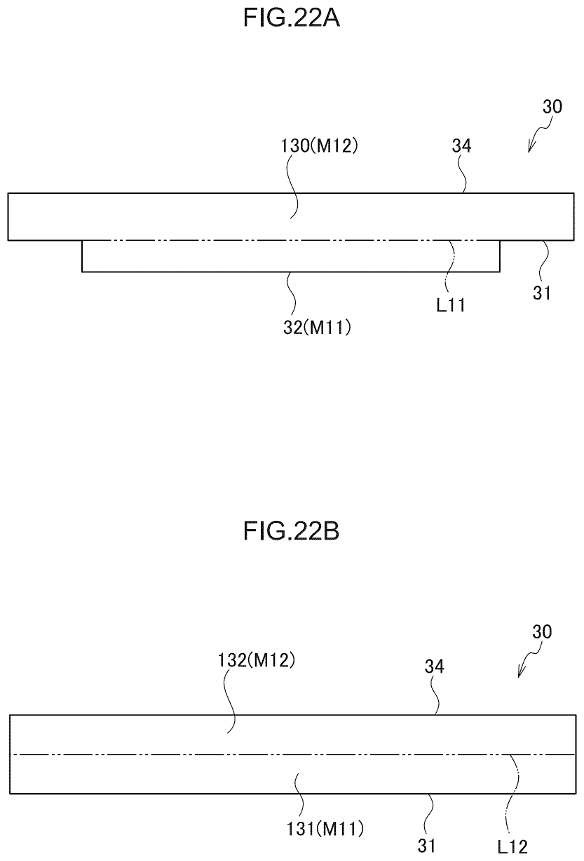

For example, the collet 30 may be formed of two or more kinds of materials with different hardnesses. In the collet 30 according to the first embodiment, the protrusion part 32 that comes into contact with the semiconductor chip C may be formed of a first material M11 as illustrated in, for example, FIG. 22A. Moreover, in the collet 30 according to the first embodiment, a part except for the protrusion part 32, in other words, a part 130 that faces the bottom surface 220 of the recessed part 22 of the holder 20 may be formed of a second material M12. The first material M11 and the second material M12 are rubber elastic bodies mainly made of natural rubber or synthetic rubber. However, the second material M12 is preferably a rubber elastic body with a hardness lower than that of the first material M11 so that the part 130 of the collet 30 elastically deforms when contacting the protrusion part 23, and the step parts 24 and 25 of the holder 20. A dashed and double-dotted line L11 in FIG. 22A represents the boundary between the first material M11 and the second material M12.

In the collet 30 according to the second embodiment, likewise, a part 131 that comes into contact with the semiconductor chip C may be formed of the first material M11 as illustrated in, for example, FIG. 22B. A dashed and double-dotted line L12 in FIG. 22B represents the boundary between the first material M11 and the second material M12.

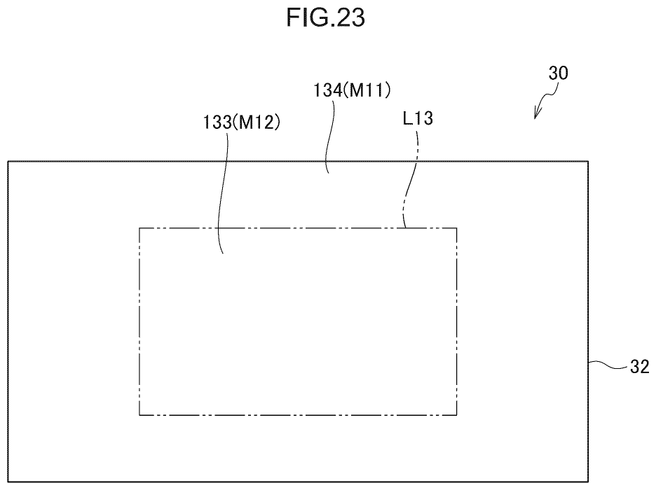

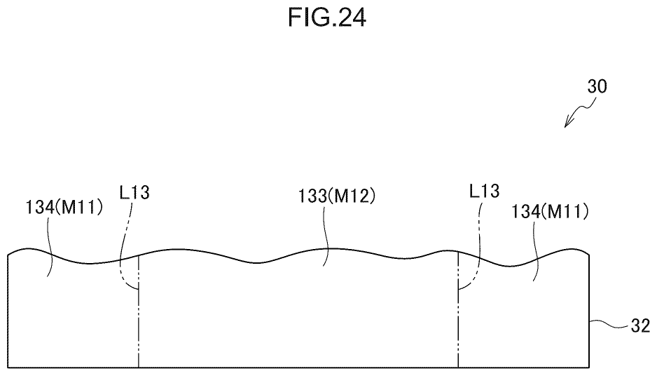

FIG. 23 is a bottom view illustrating a bottom surface structure of the protrusion part 32 of the collet 30 according to the first embodiment. FIG. 24 is a front view illustrating a front structure of the protrusion part 32 of the collet 30 according to the first embodiment. As illustrated in FIGS. 23 and 24, in the protrusion part 32 as a part that comes into contact with the semiconductor chip C, a central part 133 and an outer peripheral part 134 provided at the outer periphery of the central part 133 may be formed of different materials. Specifically, the central part 133 of the protrusion part 32 is formed of the first material M11. The outer peripheral part 134 of the protrusion part 32 is formed of the second material M12. In FIGS. 23 and 24, a dashed and double-dotted line L13 represents the boundary between the first material M11 and the second material M12. The semiconductor chip C potentially curves along the shape of the collet 30 as illustrated in FIG. 15 when the semiconductor chip C is adhered to the collet 30 by suction, and thus the first material M11 desirably has a hardness equal to or greater than Ha50 on the Shore A scale.

The holder 20 according to the first embodiment does not necessarily need to be provided with the step parts 24 and 25. Moreover, the holder 20 according to the first embodiment may be provided with one step part or three or more step parts.

The holder 20 according to the second embodiment is not limited to the two groove parts 80 and 81 but may be provided with three or more groove parts.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor manufacturing device for connecting a semiconductor chip to a target object, the semiconductor manufacturing device comprising:
a collet that is formed of an elastic material and comes into contact with the semiconductor chip; and
a holder that holds the collet, wherein
a recessed part into which the collet is inserted is formed at a front surface of the holder, and
a protrusion part is formed at a central part of a bottom surface of the recessed part, the amount of protrusion of the protrusion part being largest from the bottom surface of the recessed part relative to any other part of the bottom surface of the recessed part.

2. The semiconductor manufacturing device according to claim 1, wherein a step part is formed around the protrusion part, the step part having a smaller amount of protrusion from the bottom surface of the recessed part than the amount of protrusion of the protrusion part.

3. The semiconductor manufacturing device according to claim 2, wherein
a plurality of the step parts are formed around the protrusion part, and
the plurality of step parts are formed such that the amount of protrusion from the bottom surface of the recessed part decreases stepwise outward away from the protrusion part.

4. The semiconductor manufacturing device according to claim 2, wherein
in the holder, a ventilation hole opened at the bottom surface of the recessed part is formed only at the step part,
a through-hole is formed in the collet, the through-hole penetrating from a front surface that contacts the semiconductor chip to a back surface that faces the bottom surface of the recessed part of the holder, and
the semiconductor manufacturing device is capable of holding the semiconductor chip in contact with the collet by applying a vacuum through the ventilation hole of the holder and the through-hole of the collet.

5. The semiconductor manufacturing device according to claim 2, wherein
the collet is formed in a rectangular parallelepiped shape,
the recessed part of the holder is formed in a rectangular parallelepiped shape corresponding to the collet, and
the step part is formed in a rectangular parallelepiped shape.

6. The semiconductor manufacturing device according to claim 5, wherein corners of the step part are deformed to extend toward corners of the recessed part of the holder.

7. The semiconductor manufacturing device according to claim 1, wherein
a plurality of groove parts in an elongated hole shape are formed on the bottom surface of the recessed part,
ventilation holes opened at bottom surfaces of the plurality of groove parts are formed in the holder,
through-holes are formed in the collet, the through-holes penetrating from a front surface that contacts the semiconductor chip to a back surface that faces the plurality of groove parts, and
the semiconductor manufacturing device is capable of holding the semiconductor chip in contact with the collet by applying a vacuum through the ventilation holes of the holder and the through-holes of the collet.

8. The semiconductor manufacturing device according to claim 7, wherein the protrusion part is formed between two predetermined groove parts adjacent to each other among the plurality of groove parts and is formed to extend in an elongated shape along the two predetermined groove parts.

9. The semiconductor manufacturing device according to claim 1, wherein the collet has a hardness equal to or greater than Ha50 on the Shore A scale and equal to or less than Ha100 on the Shore A scale.

10. The semiconductor manufacturing device according to claim 1, wherein the collet is formed of two or more kinds of materials with different hardnesses.

11. The semiconductor manufacturing device according to claim 10,
wherein the two or more kinds of materials include a first material and a second material having a hardness lower than the hardness of the first material,
the collet includes a part that is formed of the first material and comes into contact with the semiconductor chip, and
the collet includes another part that is formed of the second material and faces the bottom surface of the recessed part of the holder.

12. The semiconductor manufacturing device according to claim 1, wherein a side wall part is formed on the holder, the side wall part being flush with a side surface of the recessed part and protruding from the front surface of the holder.

13. A semiconductor device manufacturing method for connecting a semiconductor chip to a target object, the semiconductor device manufacturing method comprising:
using the semiconductor manufacturing device according to claim 1 to connect the semiconductor chip in contact with the collet to the target object.
